(19) United States
(12) Patent Application Publication
(10) Pub. No.: US 2025/0006416 A1
(43) Pub. Date: Jan. 2, 2025

(54) ISOLATION TRANSFORMER AND FABRICATION METHOD THEREOF

(71) Applicant: PULSE ELECTRONICS, INC., San Diego, CA (US)

(72) Inventors: Peter WIGLEY, San Diego, CA (US); Thomas RASCON, San Diego, CA (US); Mark GREENE, San Diego, CA (US); Mohammad SABOORI, San Diego, CA (US); Hamlet ABEDMAMOORE, San Diego, CA (US); Sheshe ZHAO, Zhuhai City, Guangdong Province (CN)

(21) Appl. No.: 18/652,372

(22) Filed: May 1, 2024

Related U.S. Application Data
(60) Provisional application No. 63/511,307, filed on Jun. 30, 2023.

(51) Int. Cl. H01F 27/28; H01F 41/02; H01F 41/04; H05K 1/18

(52) U.S. Cl. CPC H01F 27/28; H01F 41/0206; H01F 41/04; H05K 1/181; H05K 2201/1003

(57) ABSTRACT

An isolation transformer and a transformer fabrication method thereof are provided. The isolation transformer includes a printed circuit board, a planar transformer, and a common mode choke. The planar transformer and the common mode choke are disposed on the printed circuit board. The common mode choke is electrically connected to the planar transformer. The printed circuit board has a cutout structure located between the planar transformer and the common mode choke. The fabrication method includes: providing the printed circuit board including a transformer coil circuit formed in the printed circuit board; forming a cutout structure and a transformer opening in the printed circuit board; disposing a transformer core and a common mode choke on the printed circuit board. The cutout structure is located between the planar transformer and the common mode choke.

### RELATED APPLICATIONS

The present application claims the benefit of priority to U.S. Provisional Patent Application No. 63/511,307, filed Jun. 30, 2023, all of which are herein incorporated by reference.

### BACKGROUND

### Field of Invention

The present invention relates to an isolation transformer and a fabrication method thereof.

### Description of Related Art

Isolation transformers are commonly used in power management systems, for example, Automotive Battery Management Systems (BMS) or Energy Storage Systems (ESS). The transformers are used for signal communication between two electrically isolated circuits, typically provide input/output isolation of several thousand volts and require minimum creepage distances between primary and secondary circuits to comply with relevant safety standards. Typically, the isolation transformers are constructed by using wound toroid.

The toroidal transformer construction requires specialized wires or specially coated cores to meet safety requirements. These materials make it difficult to implement auto winding and termination processes and require manual processes, which introduce reliability issues and do not comply with automotive industry requirements for zero defects.

### SUMMARY

Embodiments of the present invention provide an isolation transformer and a fabrication method thereof. The isolation transformer uses planar technology for convenience of fabrication, and a cutout structure is provided for physical isolation.

In accordance with an embodiment of the present invention, the isolation transformer includes a printed circuit board, a planar transformer and a common mode choke. The planar transformer is disposed on the printed circuit board. The common mode choke is electrically connected to the planar transformer and disposed on the printed circuit board.

In accordance with an embodiment of the present invention, the isolation transformer includes a printed circuit board, a planar transformer and a common mode choke. The planar transformer is disposed on the printed circuit board. The common mode choke is electrically connected to the planar transformer and disposed on the printed circuit board. The printed circuit board has a cutout structure located between the planar transformer and the common mode choke, and a length of a first cutout portion of the cutout structure is greater than a length of a first side of the common mode choke.

In some embodiments with respect to the isolation transformer, the common mode choke is implemented as a planar device.

In some embodiments with respect to the isolation transformer, the isolation transformer further includes a header disposed on the printed circuit board and covering the planar transformer and the common mode choke.

In some embodiments with respect to the isolation transformer, the header has an opening exposing the common mode choke.

In some embodiments with respect to the isolation transformer, the header has a cutout portion located above the cutout structure.

In some embodiments with respect to the isolation transformer, the header provides a platform for the planar transformer and the planar transformer is assembled on top of the header.

In accordance with an embodiment of the present invention, the fabrication method of the isolation transformer includes: providing a printed circuit board including a transformer coil circuit formed in the printed circuit board; forming a cutout structure and a transformer opening in the printed circuit board, in which the transformer coil circuit surrounds the transformer opening; disposing a transformer core on the printed circuit board, in which a portion of the transformer core passes through the transformer opening to form a planar transformer; disposing a common mode choke on the printed circuit board, in which the cutout structure is located between the planar transformer and the common mode choke, the cutout structure has a first cutout portion extending along a first side of the common mode choke, and the common mode choke is electrically connected to the transformer.

In some embodiments with respect to the fabrication method of the isolation transformer, a length of the first cutout portion is greater than a length of the first side of the common mode choke.

In some embodiments with respect to the fabrication method of the isolation transformer, the fabrication method further includes: disposing a header on the printed circuit board, in which the planar transformer and the common mode choke are covered by the header.

In some embodiments with respect to the fabrication method of the isolation transformer, the header has an opening exposing the common mode choke.

In some embodiments with respect to the fabrication method of the isolation transformer, the header has a cutout portion, and disposing a header on the printed circuit board allows the cutout portion to be located above the cutout structure.

### BRIEF DESCRIPTION OF THE DRAWINGS

The invention can be more fully understood by reading the following detailed description of the embodiment, with reference made to the accompanying drawings as follows.

FIG. 1 is a schematic diagram showing a perspective view of an isolation transformer in accordance with embodiments of the present invention.

FIG. 2 is a schematic diagram showing a top view of the isolation transformer in accordance with embodiments of the present invention.

FIG. 3 is a schematic diagram showing a front view of the isolation transformer in accordance with embodiments of the present invention.

FIG. 4 is a schematic diagram showing a top view of the isolation transformer in accordance with embodiments of the present invention.

FIG. 5 is a schematic diagram showing a front view of the isolation transformer in accordance with embodiments of the present invention.

FIG. 6 is a circuit diagram representing the electric connection between the points and the planar transformer/common mode choke in accordance with embodiments of the present invention.

FIG. 7 and FIG. 8 are schematic diagrams showing layers of the printed circuit board in accordance with embodiments of the present invention.

FIG. 9 is a schematic diagram showing a top view of the isolation transformer in accordance with embodiments of the present invention.

FIG. 10 is a schematic diagram showing a top view of the isolation transformer in accordance with the embodiments of the present invention.

FIG. 11 is a schematic diagram showing a perspective view of the isolation transformer with a header covering the planar transformer and the common mode choke in accordance with the embodiments of the present invention.

FIG. 12A is a schematic diagram showing a cross-sectional view of an isolation transformer along a cut line A-A′ in accordance with embodiments of the present invention.

FIG. 12B is a schematic diagram showing a cross-sectional view of an isolation transformer along a cut line A-A′ in accordance with embodiments of the present invention.

FIG. 13 is a schematic diagram showing a cross-sectional view of an isolation transformer along a cut line A-A′ in accordance with embodiments of the present invention.

FIG. 14 is a schematic diagram showing a side view of the isolation transformer in accordance with one embodiment of the present invention where the assembly is inverted.

FIG. 15 is a diagram showing one embodiment of the invention where the common mode choke is implemented as a planar device, in which only one winding layer is shown for clarity.

FIG. 16 is flowchart showing a fabrication method 1400 of the isolation transformer in accordance with embodiments of the present invention.

### DETAILED DESCRIPTION

Specific embodiments of the present invention are further described in detail below with reference to the accompanying drawings, however, the embodiments described are not intended to limit the present invention and it is not intended for the description of operation to limit the order of implementation. Moreover, any device with equivalent functions that is produced from a structure formed by a recombination of elements shall fall within the scope of the present invention. Additionally, the drawings are only illustrative and are not drawn to actual size.

The using of “first”, “second”, “third”, etc. in the specification should be understood for identifying units or data described by the same terminology but are not referred to particular order or sequence.

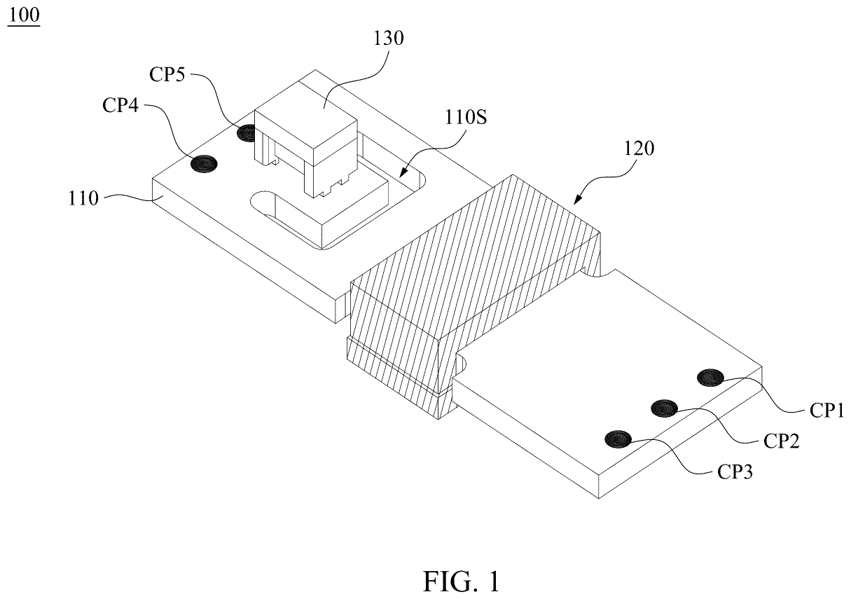

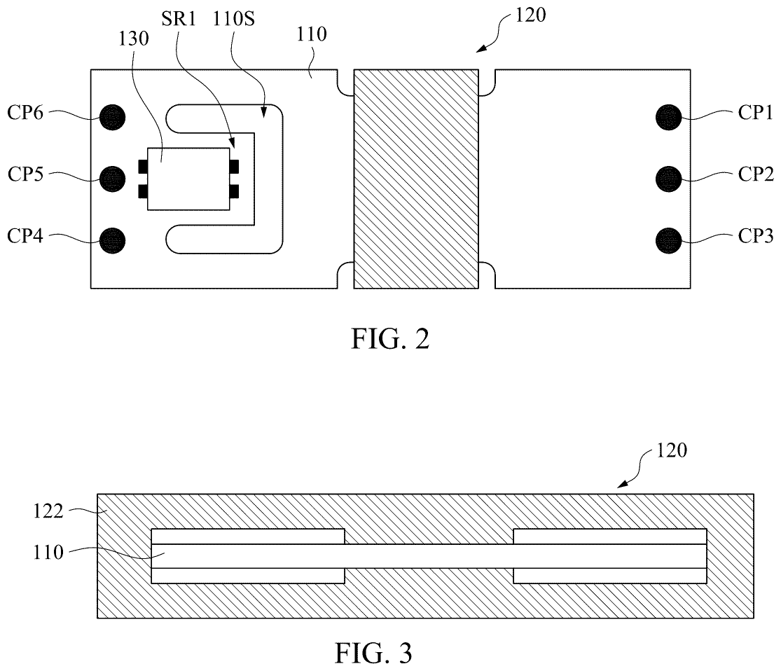

Referring to FIG. 1 to FIG. 3, FIG. 1 is a schematic diagram showing a perspective view of an isolation transformer 100 in accordance with embodiments of the present invention, FIG. 2 is a schematic diagram showing a top view of the isolation transformer 100, and FIG. 3 is a schematic diagram showing a front view of the isolation transformer 100. The isolation transformer 100 includes a printed circuit board 110, a planar transformer 120 and a common mode choke 130. The planar transformer 120 and the common mode choke 130 are disposed on the printed circuit board 110 and electrically connected to each other. In this embodiment, the printed circuit board 110 is a printed circuit board (PCB), and the common mode choke 130 is a SMT (Surface Mount Technology) component disposed on the solder pads of the printed circuit board 110, but embodiments of the present invention are not limited thereto.

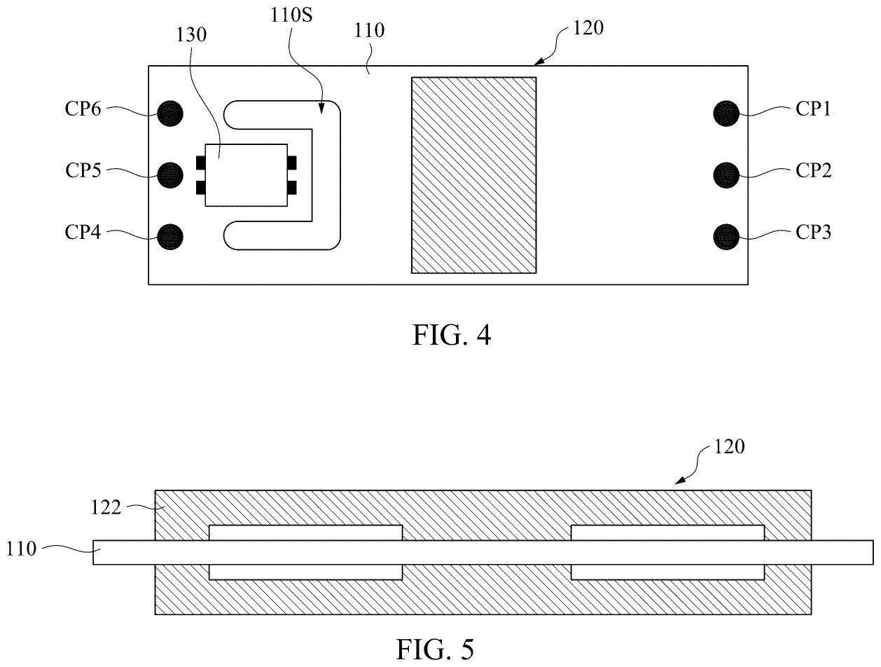

The planar transformer 120 includes a transformer core 122 and a transformer coil circuit formed in the printed circuit board 110. The transformer core 122 is disposed on the printed circuit board 110 and a portion of the transformer core 122 penetrates the printed circuit board 110 as shown in FIG. 3. In this embodiment, the printed circuit board 110 has one transformer opening for the transformer core 122, thus only one portion of the transformer core 122 passes through the transformer opening (penetrates the printed circuit board 110). However, embodiments of the present invention are not limited thereto. In some embodiments, the printed circuit board 110 has three openings, thus three portions of the transformer core 122 pass through the three openings to form the planar transformer 120, as shown in FIG. 4 and FIG. 5.

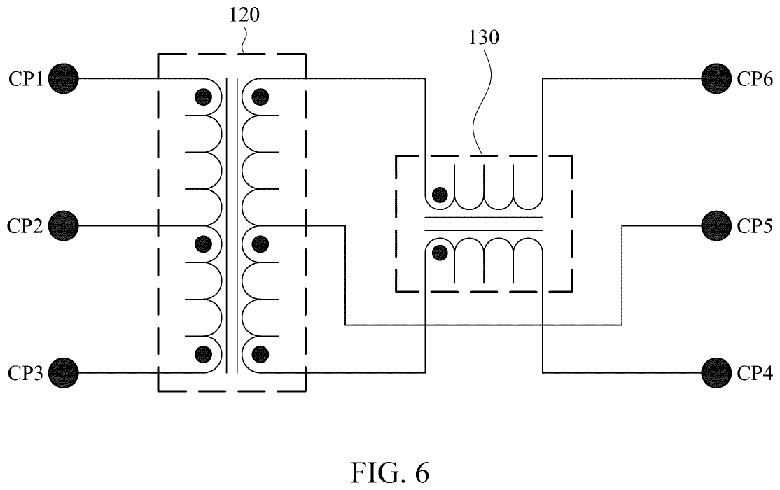

Connection points CP1-CP6 are formed on the printed circuit board 110 and electrically connected to the planar transformer 120 and the common mode choke 130 for input/output of the isolation transformer 100. In some embodiments, the connection points CP1-CP6 includes solder pads and vias underlying the solder pads for electric connection between the points CP1-CP6 and the planar transformer 120/common mode choke 130. A circuit diagram representing the electric connection between the points CP1-CP6 and the planar transformer 120/common mode choke 130 is shown in FIG. 6.

The printed circuit board 110 has a cutout structure 110S located between the planar transformer 120 and the common mode choke 130, and the cutout structure 110S has a portion extending along a side of the common mode choke 130, thereby ensuring that a sufficient creepage distance between the planar transformer 120 and the common mode choke 130 is achieved.

In this embodiment, as shown in FIG. 2, the cutout structure 110S is a U-shaped cutout structure defining a surrounded region SR1 on the printed circuit board 110, and a portion of the common mode choke 130 is located in the surrounded region SR1. In other words, the cutout structure 110S extends along three sides of the common mode choke 130. Therefore, the common mode choke 130 is physically isolated from the planar transformer 120 by using the cutout structure 110S, and a sufficient creepage distance between the planar transformer 120 and the common mode choke 130 is ensured.

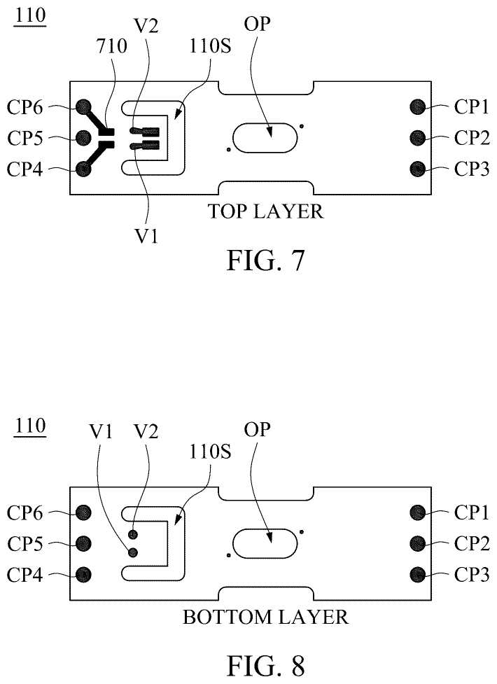

FIG. 7 is a schematic diagram showing the top layer of a multi-layer, laminated printed circuit board 110 in accordance with embodiments of the present invention. On this layer, solder pads for the connection points CP1-CP6 and the common mode choke 130 are provided. Specifically, four pads 710 are provided for soldering of the common mode choke 130, in which two of the pads 170 are located in the region defined by the cutout structure 110S. Vias V1&V2 allow for electrical connection between the common mode choke on the top layer and the transformer coil on internal layer 1−n, in which n is a positive integer.

FIG. 8 is a schematic diagram showing the bottom layer of a multi-layer, laminated printed circuit board 110 in accordance with embodiments of the present invention. On this layer the via structures of the connection points CP1-CP6 and the vias V1-V2 penetrating the printed circuit board 110 are presented.

The transformer coil circuit is implemented in internal layers 1−n, and electrically connected to connection points CP1-CP3, CP5 and V1&V2, providing electrical connection to the common mode choke. Additional vias located between internal layers 1−n, are not shown.

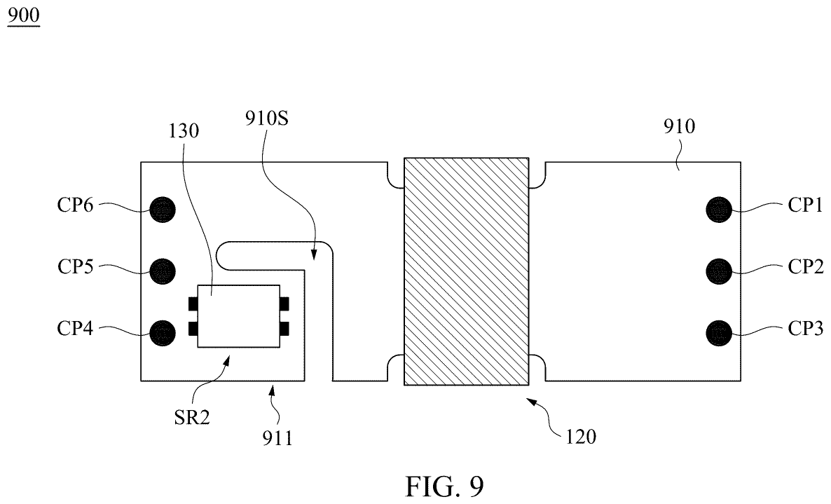

Referring to FIG. 9, FIG. 9 is a schematic diagram showing a top view of the isolation transformer 900 in accordance with embodiments of the present invention. The isolation transformer 900 is similar to the isolation transformer 100, but a difference is in that a printed circuit board 910 of the isolation transformer 900 has a L-shaped cutout structure 910S. The L-shaped cutout structure 910S and an edge 911 of the printed circuit board 910 define a surrounded region SR2 on the printed circuit board 910, and a portion of the common mode choke 130 is located in the surrounded region SR2. In other words, the cutout structure 910S extends along two sides of the common mode choke 130. Therefore, the common mode choke 130 is physically isolated from the planar transformer 120 by using the cutout structure 910S, and a sufficient creepage distance between the planar transformer 120 and the common mode choke 130 is ensured.

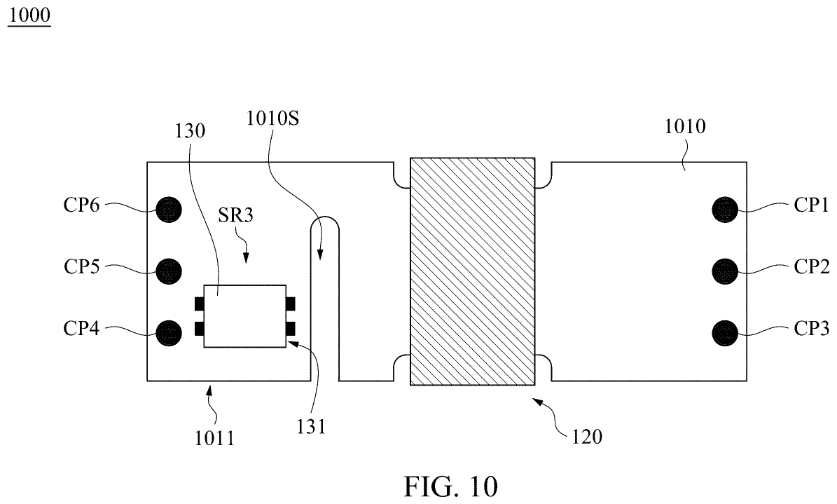

Referring to FIG. 10, FIG. 10 is a schematic diagram showing a top view of the isolation transformer 1000 in accordance with embodiments of the present invention. The isolation transformer 1000 is similar to the isolation transformer 1000, but a difference is in that a printed circuit board 1010 of the isolation transformer 1000 has a straight-line cutout structure 1010S extending from a side 1011 of the printed circuit board 1010 and along a side 131 of the common mode choke 130. The straight-line cutout structure 1010S and the side 1011 of the printed circuit board 1010 define a region SR3 on the printed circuit board 1010, and the common mode choke 130 is located in the region SR3. In other words, the straight-line cutout structure 1010S extends along one side of the common mode choke 130. Therefore, the common mode choke 130 is physically isolated from the planar transformer 120 by using the straight-line cutout structure 1010S, and a sufficient creepage distance between the planar transformer 120 and the common mode choke 130 is ensured.

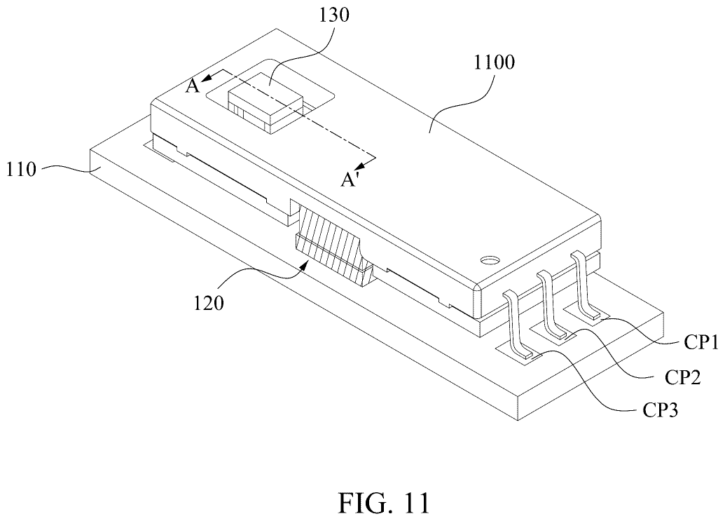

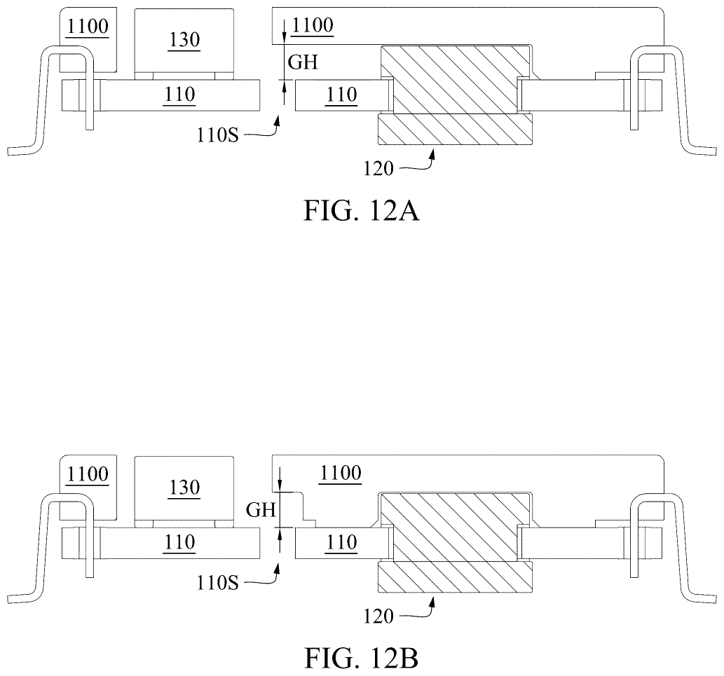

Referring to FIG. 11 and FIG. 12A/12B, FIG. 11 is a schematic diagram showing a perspective view of the isolation transformer 100 with a header 1100 covering the planar transformer 120 and the common mode choke 130, and FIG. 12A/12B is a schematic diagram showing a cross-sectional view along a cut line A-A′ in FIG. 11 in accordance with embodiments of the present invention. In this embodiment, the header 1100 has an opening exposing the common mode choke 130, but embodiments of the present invention are no limited thereto. In some embodiments, the opening of the header 1100 can be omitted, and the exposing of the common mode choke 130 is not required.

As shown FIG. 12A, a gap GH of 1 mm or greater between the printed circuit board 110 and the header 1100 is presented after the header 1100 is disposed on the printed circuit board 110, ensuring that the cutout structure 110S is not bridged for the purpose of creepage distance measurement.

As shown in FIG. 12B, in one embodiment of the invention, the gap GH of 1 mm or greater is implemented with a cutout portion 1110 located above the cutout structure 110S.

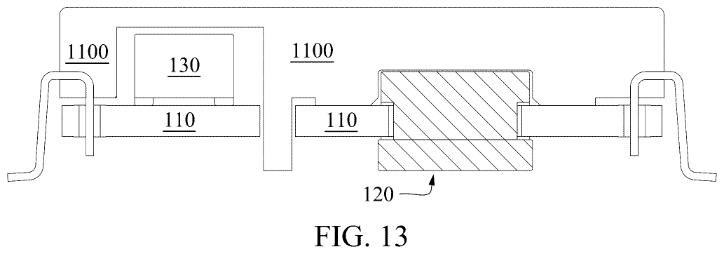

As shown in FIG. 13, in one embodiment of the invention, a portion of the header 1100 protrudes through the cutout 110S of the printed circuit board 110.

Further, the material of the header 1100 is non-conductive material. For example, in some embodiments, the material of the header 1100 is plastic material, but embodiments of the present invention are not limited thereto.

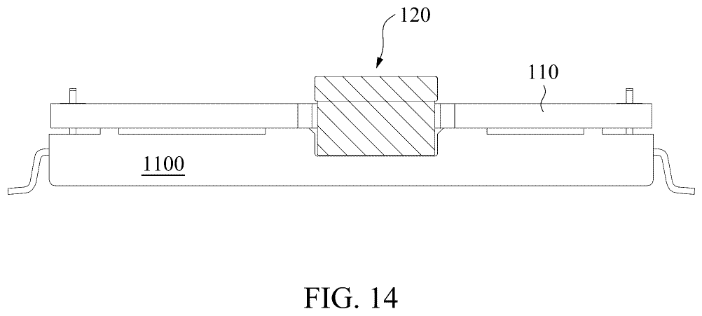

As shown in FIG. 14, in one embodiment of the invention, the assembly is inverted so that the header 1100 provides a platform for the planar transformer 120 and the planar transformer 120 is assembled on top of the header 1100.

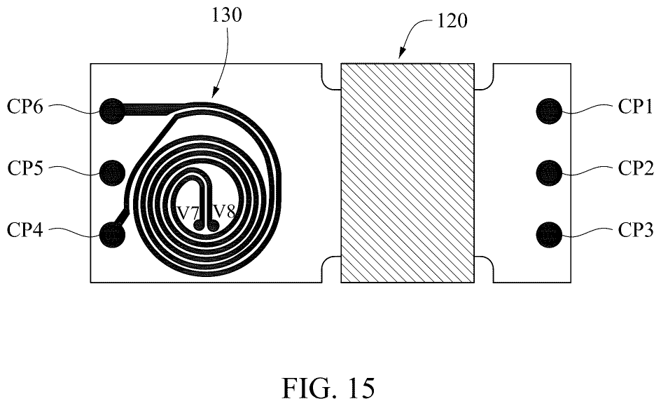

As shown in FIG. 15, in one embodiment of the invention, the winding of the common mode choke 130 is formed in multiple internal layers of the printed circuit board. Vias V7 and V8 are formed to allow for electrical connection between the common mode choke and the transformer coil 120. Additional vias, not shown, allow for connection between internal layers.

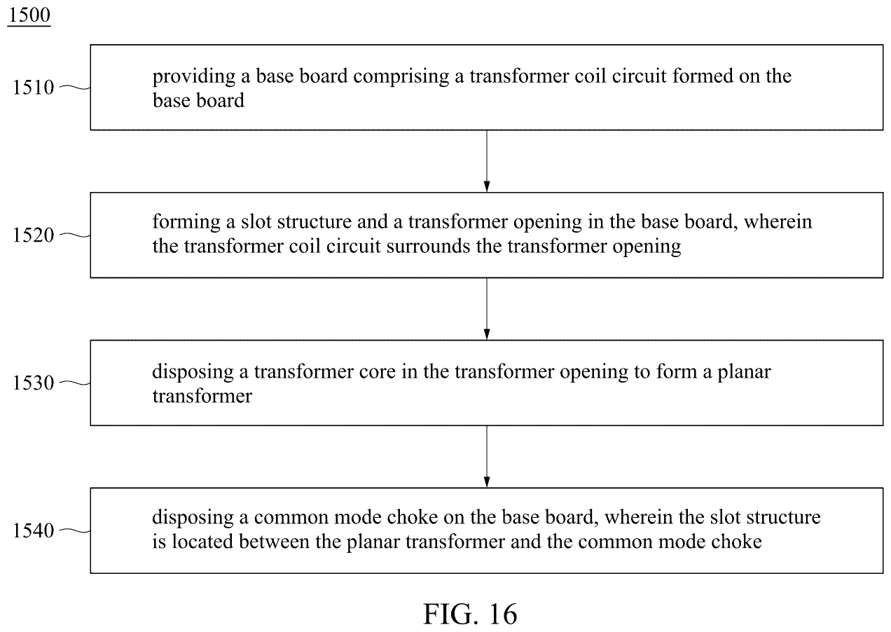

Referring to FIG. 16, FIG. 16 is flowchart showing a fabrication method 1500 of the isolation transformer 100 in accordance with embodiments of the present invention. The fabrication method 1400 provides a simplified and convenient method to fabricate the isolation transformer 100, and manual processes are significantly decreased.

In step 1510, the printed circuit board 110 including the transformer coil circuit TC is provided. In step 1520, the cutout structure 110S and the transformer opening OP are formed in the printed circuit board 110. As show in FIG. 7 and FIG. 8, the transformer coil circuit TC can be formed in interlayers of the printed circuit board 110 and solder pads can be provided, and the cutout structure 110S is formed between the transformer coil circuit TC and the solder pads for the common mode choke 130.

The transformer opening OP is formed to allow the transformer coil circuit TC to surround the transformer opening OP.

In step 1530, the transformer core 122 is disposed on the printed circuit board 110, in which a portion of the transformer core 122 passes through the transformer opening OP to form the planar transformer 120.

In step 1540, the common mode choke 130 is disposed on the printed circuit board 110. Since the cutout structure 110S is formed between the transformer coil circuit TC and the solder pads for the common mode choke 130, the cutout structure 110S is located between the common mode choke 130 and the planar transformer 120.

It can be understood that planar transformer technology is used in the fabrication method 1500 to fabricate the planar transformer 120. Therefore, winding processes and termination processes can be omitted. Further, since the planar transformer technology is used in the fabrication method 1500, the cutout structure 110S is also provided to physically isolate the common mode choke 130 from the planar transformer 120 to ensure sufficient creepage distances between primary and secondary circuits to comply with relevant safety standard.

Although the present invention has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An isolation transformer, comprising:
a printed circuit board;
a planar transformer disposed on the printed circuit board; and
a common mode choke electrically connected to the planar transformer and disposed on the printed circuit board.

2. An isolation transformer, comprising:
a printed circuit board;
a planar transformer disposed on the printed circuit board; and
a common mode choke electrically connected to the planar transformer and disposed on the printed circuit board;
wherein the printed circuit board has a cutout structure located between the planar transformer and the common mode choke, and a length of a first cutout portion of the cutout structure is greater than a length of a first side of the common mode choke.

3. The isolation transformer of claim 1, where the common mode choke is implemented as a planar device.

4. The isolation transformer of claim 2, further comprising:
a header disposed on the printed circuit board and covering the planar transformer and the common mode choke.

5. The isolation transformer of claim 4, wherein the header has an opening exposing the common mode choke.

6. The isolation transformer of claim 4, wherein the header has a cutout portion located above the cutout structure.

7. The isolation transformer of claim 4, wherein the header provides a platform for the planar transformer and the planar transformer is assembled on top of the header.

8. A fabrication method of an isolation transformer, comprising:
providing a printed circuit board comprising a transformer coil circuit formed in the printed circuit board;
forming a cutout structure and a transformer opening in the printed circuit board, wherein the transformer coil circuit surrounds the transformer opening;
disposing a transformer core on the printed circuit board, wherein a portion of the transformer core passes through the transformer opening to form a planar transformer;
disposing a common mode choke on the printed circuit board, wherein a cutout structure is located between the planar transformer and the common mode choke, the cutout structure has a first cutout portion extending along a first side of the common mode choke, and the transformer core is electrically connected to the transformer.

9. The fabrication method of claim 8, wherein a length of the first cutout portion is greater than a length of the first side of the common mode choke.

10. The fabrication method of claim 8, further comprising:
disposing a header on the printed circuit board, wherein the planar transformer and the common mode choke are covered by the header.

11. The fabrication method of claim 10, wherein the header has an opening exposing the common mode choke.

12. The fabrication method of claim 10, wherein the header has a cutout portion, and disposing a header on the printed circuit board allows the cutout portion to be located above the cutout structure.
